(19) United States
(12) Patent Application Publication
(10) Pub. No.: US 2026/0293573 A1
(43) Pub. Date: Sep. 24, 2026

(54) SUBSTRATE PROCESSING APPARATUS

(71) Applicant: SCREEN Holdings Co., Ltd., Kyoto (JP)

(72) Inventors: Kota TANIKAWA, Kyoto-shi (JP); Yuichi TAKAYAMA, Kyoto-shi (JP); Manabu TAKUSARI, Kyoto-shi (JP); Hiroyuki YASHIKI, Kyoto-shi (JP)

(21) Appl. No.: 19/570,873

(22) Filed: Mar. 18, 2026

(30) Foreign Application Priority Data
Mar. 24, 2025 (JP) 2025-048456

(51) Int. Cl. H10P 72/00; H10P 72/76

(52) U.S. Cl. CPC H10P 72/0414; H10P 72/7618

(57) ABSTRACT

A substrate processing apparatus includes: a spin chuck; a rotation mechanism; a guard container having a guard opening; a shielding plate provided above a substrate, and is capable of closing the guard opening; an inert gas supply mechanism that supplies an inert gas into an internal space surrounded by the guard container and the shielding plate; a rotation nozzle plate disposed in a mounting hole penetrating the shielding plate in a vertical direction, and is rotatable with respect to the shielding plate about a second vertical axis arranged at a position different from a first vertical axis; a nozzle that is provided at a position away from the second vertical axis in the rotation nozzle plate, and discharges a treatment liquid to the substrate held by the spin chuck; and a nozzle rotation mechanism that rotates the rotation nozzle plate about the second vertical axis.

### CROSS-REFERENCE TO RELATED APPLICATIONS

This application claims priority to Japanese Patent Application No. 2025-048456 filed Mar 24, 2025, the subject matter of which is incorporated herein by reference in entirety.

### BACKGROUND

### Technical Field

The present invention relates to a substrate processing apparatus that processes a substrate. Examples of the substrate include a semiconductor substrate, a substrate for a flat panel display (FPD), a glass substrate for a photomask, a substrate for an optical disk, a substrate for a magnetic disk, a ceramic substrate, a substrate for a solar cell, and the like. Examples of the FPD include a liquid crystal display device, an organic electroluminescence (EL) display device, and the like.

### Related Art

In a back end of line (BEOL) process (that is, a wiring process) in a semiconductor manufacturing process, there are many processes in which metal wiring is exposed. There is known a problem that the metal wiring is corroded by oxygen in the air and oxygen in liquid during such processes. As devices therefor, there are the following devices (see, for example, JP 6762824 B2, JP 6402071 B2, and JP 6670674 B2).

A substrate processing apparatus includes a substrate holding unit that holds a substrate, a shielding plate (shielding member) that faces an upper surface of the substrate, and a nozzle disposed at the center of the shielding plate. A space (small space) is formed between the substrate held by the substrate holding unit and the shielding plate. An inert gas is supplied to the space. Further, JP 6402071 B2 discloses a labyrinth seal.

### SUMMARY

However, in the conventional substrate processing apparatus, a position of the nozzle is fixed to the center of the shielding plate, and scanning cannot be performed.

For example, it is assumed that the substrate processing apparatus is not provided with the shielding plate, and includes the substrate holding unit, the nozzle, and a nozzle moving mechanism that moves the nozzle in a housing (chamber). In this case, the nozzle is movable by the nozzle moving mechanism. However, when the inert gas is supplied into the housing, an amount of the inert gas used may be enormous.

Further, JP 6670674 B2 discloses a through hole formed in a side wall of a shielding member and an IPA nozzle that can pass through the through hole. In this case, the IPA nozzle can move in a radial direction of a substrate through the through hole. However, there is a possibility that an external gas flows into a space between the shielding member and an upper surface of the substrate through the through hole, or gas in the space flows out to an outside through the through hole. Therefore, there is a possibility that it is difficult to maintain a state in which oxygen in the air is reduced. In addition, if the number of nozzles is increased, there is a possibility that the through hole becomes large.

That is, the conventional substrate processing apparatus has structural constraints on performing nozzle scanning.

The present invention has been made in view of such circumstances, and an object thereof is to provide a substrate processing apparatus capable of performing nozzle scanning while reducing oxygen in the air in a small space.

In order to achieve such an object, the present invention has the following configuration. That is, a substrate processing apparatus that processes a substrate according to the present invention includes: a chuck configured to hold the substrate in a horizontal posture; a rotation mechanism configured to rotate the substrate held by the chuck, about a first vertical axis passing through a center of the substrate; a guard container having a side wall surrounding a side of the chuck, and a guard opening formed by an upper inner peripheral edge of the side wall; a shielding plate provided above the substrate held by the chuck, and is capable of closing the guard opening; an inert gas supply mechanism configured to supply an inert gas into an internal space surrounded by the guard container and the shielding plate; a rotation nozzle plate disposed in a mounting hole penetrating the shielding plate in a vertical direction, and is rotatable with respect to the shielding plate about a second vertical axis arranged at a position different from the first vertical axis; a nozzle provided at a position away from the second vertical axis in the rotation nozzle plate, and configured to discharge a treatment liquid to the substrate held by the chuck; and a nozzle rotation mechanism configured to rotate the rotation nozzle plate about the second vertical axis.

According to the substrate processing apparatus of the present invention, the shielding plate closes the guard opening of the guard container, and the inert gas is supplied to the internal space surrounded by the guard container and the shielding plate. The rotation nozzle plate is disposed in the mounting hole penetrating the shielding plate in the vertical direction. The rotation nozzle plate is rotatable with respect to the shielding plate about the second vertical axis arranged at the position different from the first vertical axis passing through the center of the substrate. The nozzle is provided at the position away from the second vertical axis in the rotation nozzle plate. The nozzle rotation mechanism rotates the rotation nozzle plate about the second vertical axis, so that the nozzle moves about the second vertical axis. Therefore, nozzle scanning can be performed while reducing oxygen in the air in a small space.

In the substrate processing apparatus described above, it is preferable that the rotation nozzle plate includes a supporting member configured to support the shielding plate, when the supporting member of the rotation nozzle plate supports the shielding plate, the rotation nozzle plate is configured to move integrally with the shielding plate in the vertical direction, and when the shielding plate is supported on an upper portion of the guard container, the rotation nozzle plate is configured to be separated from the shielding plate. The rotation nozzle plate can be integrated with the shielding plate or separated from the shielding plate.

In the substrate processing apparatus described above, it is preferable that the nozzle rotation mechanism is configured to move the nozzle between the center of the substrate and a peripheral edge of the substrate in plan view, by rotating the rotation nozzle plate about the second vertical axis. As a result, the nozzle can be moved between the center of the substrate and the peripheral edge of the substrate.

In the substrate processing apparatus described above, it is preferable that the nozzle includes a plurality of discharge openings on a lower surface of the nozzle, and a first discharge opening of the plurality of discharge openings is configured to discharge the treatment liquid. The plurality of discharge openings can be moved along with the movement of the nozzle.

In the substrate processing apparatus described above, it is preferable that the nozzle is provided on a virtual circle with the second vertical axis as a central axis, in the rotation nozzle plate, and the virtual circle is configured to pass through the center of the substrate held by the chuck in plan view. The nozzle can be moved to the center of the substrate in plan view.

In the substrate processing apparatus described above, it is preferable that the nozzle is provided on a virtual circle with the second vertical axis as a central axis, in the rotation nozzle plate, and the virtual circle is configured to pass through a position deviated from the substrate held by the chuck in plan view. The nozzle can be moved to an outside of the substrate in plan view. As a result, pre-dispensing can be performed from the nozzle to the outside of the substrate.

It is preferable that the substrate processing apparatus described above further includes a plurality of nozzles including the nozzle, and each of the plurality of nozzles is provided at a position away from the second vertical axis in the rotation nozzle plate. Since the plurality of nozzles are provided in the rotation nozzle plate, the plurality of nozzles can be moved.

It is preferable that the substrate processing apparatus described above further includes a plurality of nozzles including the nozzle, and the plurality of nozzles are provided on a virtual circle with the second vertical axis as a central axis, in the rotation nozzle plate. Since the plurality of nozzles are provided on the virtual circle with the second vertical axis as the central axis, trajectories of the plurality of nozzles can be made the same.

In the substrate processing apparatus described above, it is preferable that the virtual circle is configured to pass through the center of the substrate held by the chuck in plan view. Since the virtual circle passes through the center of the substrate in plan view, each of the plurality of nozzles can pass through the center of the substrate.

In the substrate processing apparatus described above, it is preferable that the virtual circle is configured to pass through a position deviated from the substrate held by the chuck in plan view. When the nozzle rotation mechanism rotates the rotation nozzle plate, the nozzle can be moved to the outside of the substrate in plan view. As a result, pre-dispensing can be performed from each nozzle to the outside of the substrate.

It is preferable that the substrate processing apparatus described above further includes a cleaning nozzle provided on a lower surface of the rotation nozzle plate, and configured to discharge a cleaning liquid along the lower surface of the rotation nozzle plate. Since the cleaning nozzle is provided on the lower surface of the rotation nozzle plate, a direction of the cleaning nozzle can be swung as the rotation nozzle plate swings about the second vertical axis.

In the substrate processing apparatus described above, it is preferable that an upper portion of the guard container and a lower surface of a peripheral edge portion of the shielding plate have a labyrinth seal. It is possible to suppress outside air from entering the internal space from between the guard container and the shielding plate.

In the substrate processing apparatus described above, it is preferable that the rotation nozzle plate has a flange protruding to an outer peripheral side, the shielding plate has an annular portion protruding to the mounting hole, and an upper surface of the flange and a lower surface of the annular portion have a labyrinth seal. It is possible to suppress outside air from entering the internal space from between the shielding plate and the rotation nozzle plate.

In the substrate processing apparatus described above, it is preferable that the inert gas supply mechanism is configured to supply the inert gas to the labyrinth seal, and to supply the inert gas into the internal space via the labyrinth seal. The internal space can be filled with the inert gas via the labyrinth seal while enhancing airtightness of the labyrinth seal.

In the substrate processing apparatus described above, it is preferable that the guard container includes a guard-side fitting member provided on an upper surface of the side wall, the shielding plate includes a plate-side fitting member provided on a lower surface of the shielding plate, and the plate-side fitting member is fitted to the guard-side fitting member. The shielding plate can be integrated with the guard container.

In the substrate processing apparatus described above, it is preferable that the guard container is configured not to be rotated about each of the first vertical axis and the second vertical axis. The shielding plate fitted to the guard container is also not rotated about each of the first vertical axis and the second vertical axis.

It is preferable that the substrate processing apparatus described above further includes a lifting and lowering mechanism configured to move the shielding plate and the rotation nozzle plate in the vertical direction. The lifting and lowering mechanism can move the shielding plate and the rotation nozzle plate in the vertical direction.

According to a substrate processing apparatus of the present invention, nozzle scanning can be performed while reducing oxygen in the air in a small space.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a longitudinal sectional view showing a schematic configuration of a substrate processing apparatus according to a first embodiment, and is a diagram showing a state in which a shielding plate and a rotation nozzle plate are moved to a processing position;

FIG. 2 is a diagram showing a state in which the shielding plate and the rotation nozzle plate are moved to a retraction position;

FIG. 3 is a diagram showing a fitting structure of the shielding plate and the rotation nozzle plate;

FIG. 4 is a diagram showing a fitting structure of a guard container and the shielding plate;

FIG. 5 is a longitudinal sectional view showing a labyrinth seal between the guard container and the shielding plate;

FIG. 6 is a longitudinal sectional view showing a labyrinth seal between the shielding plate and the rotation nozzle plate;

FIG. 7 is a diagram showing a lower surface of a single nozzle;

FIG. 8 is a diagram showing a configuration for supplying a treatment liquid and an inert gas to the nozzle;

FIG. 9 is a plan view showing an arrangement of a substrate, the shielding plate, the rotation nozzle plate, and the nozzle;

FIG. 10 is a block diagram for describing a configuration related to control;

FIG. 11 is a flowchart for describing an operation of the substrate processing apparatus;

FIG. 12 is a side view for describing the operation of the substrate processing apparatus;

FIG. 13 is a side view for describing the operation of the substrate processing apparatus;

FIG. 14 is a diagram for describing an effect;

FIG. 15 is a plan view showing a plurality of nozzles provided in a rotation nozzle plate according to a second embodiment;

FIG. 16 is a plan view showing a plurality of nozzles provided in a rotation nozzle plate according to a modification of the second embodiment;

FIG. 17 is a plan view showing an arrangement of a substrate, a virtual circle, and a nozzle according to a third embodiment;

FIG. 18 is a longitudinal sectional view showing an example of pre-dispensing according to the third embodiment; and

FIG. 19 is a longitudinal sectional view showing a schematic configuration of a substrate processing apparatus according to a fourth embodiment.

### DETAILED DESCRIPTION

Hereinafter, embodiments of the present invention will be described.

### First embodiment

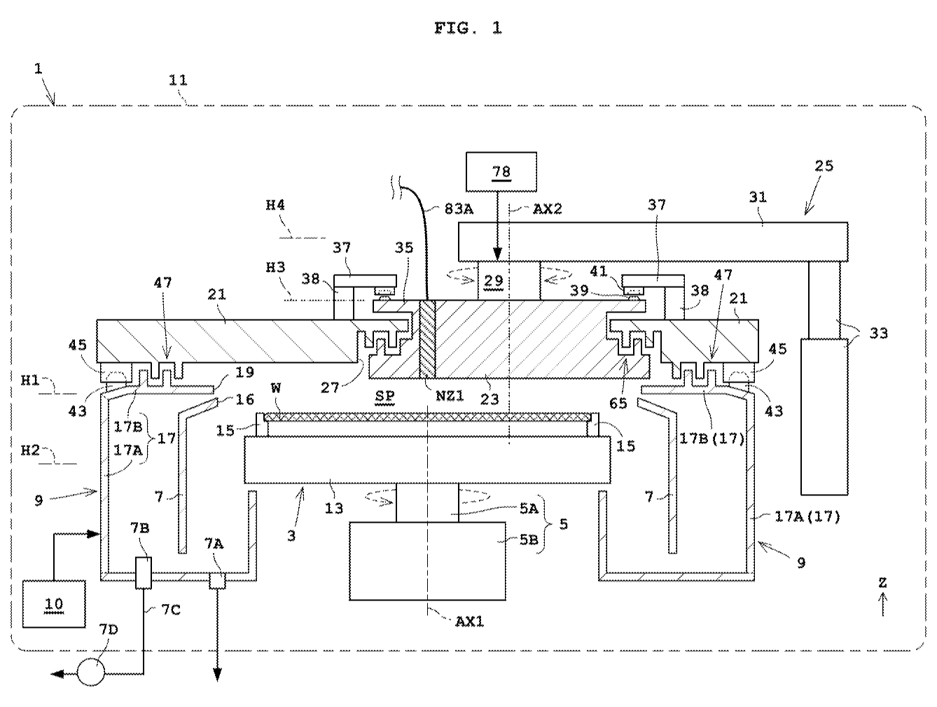

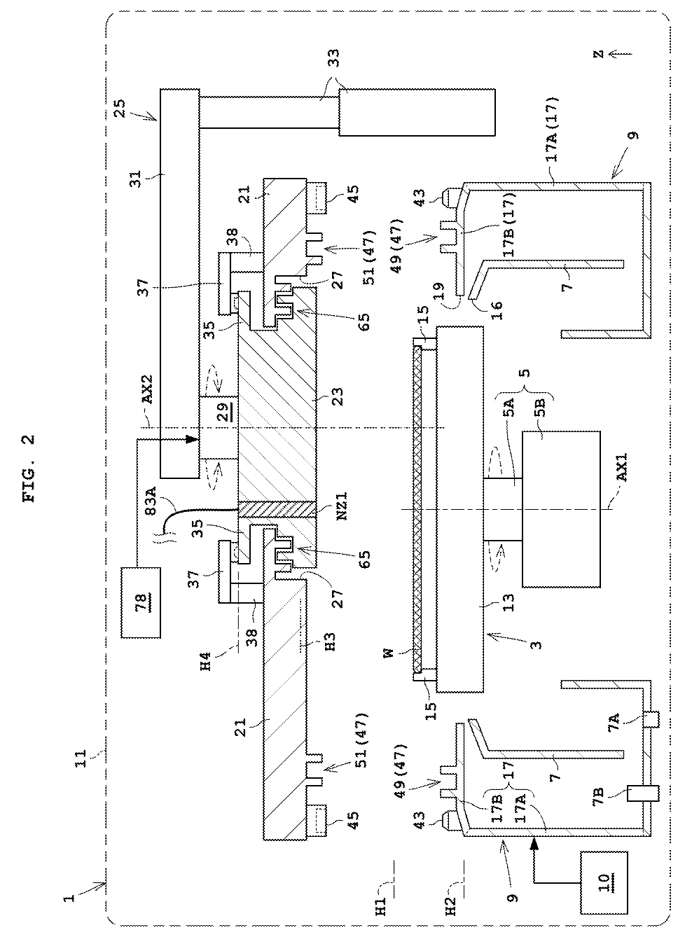

Hereinafter, a first embodiment of the present invention will be described with reference to the drawings. FIG. 1 is a longitudinal sectional view showing a schematic configuration of a substrate processing apparatus 1 according to the first embodiment, and is a diagram showing a state in which a shielding plate 21 and a rotation nozzle plate 23 are moved to a processing position. FIG. 2 is a diagram showing a state in which the shielding plate 21 and the rotation nozzle plate 23 are moved to a retraction position.

### 1. Configuration of substrate processing apparatus

Reference is made to FIGS. 1 and 2. The substrate processing apparatus 1 processes a substrate W. The substrate W is formed in, for example, a disk shape. The substrate processing apparatus 1 includes a spin chuck 3, a rotation mechanism 5, a cup 7, a guard container 9, a guard lifting and lowering mechanism 10, and a housing 11. The spin chuck 3, the rotation mechanism 5, the cup 7, the guard container 9, and the guard lifting and lowering mechanism 10 are accommodated in the housing 11. The housing 11 is a container.

The spin chuck 3 holds the substrate W in a horizontal posture. The spin chuck 3 includes a disk-shaped spin base 13 and at least three holding pins 15 provided on an upper surface of the spin base 13. The at least three holding pins 15 are disposed around a vertical axis AX1 at equal angular intervals, for example. The spin chuck 3 grips a side surface of the substrate W in the horizontal posture using the at least three holding pins 15. The spin chuck 3 may be a vacuum chuck that holds a central portion of a lower surface of the substrate W by vacuum suction.

The rotation mechanism 5 rotates the substrate W held by the spin chuck 3 about the vertical axis AX1 passing through the center of the substrate W. In other words, the rotation mechanism 5 rotates the spin chuck 3 holding the substrate W about the vertical axis AX1. The rotation mechanism 5 includes a rotation shaft 5A and an electric motor 5B. An upper end of the rotation shaft 5A is fixed to a lower surface of the spin chuck 3. The rotation shaft 5A extends downward from the spin chuck 3. The electric motor 5B rotates the spin chuck 3 about the vertical axis AX1 via the rotation shaft 5A.

The cup 7 is a cylindrical container centered on the vertical axis AX1. The cup 7 surrounds the spin chuck 3 and a side of the substrate W held by the spin chuck 3. In addition, the cup 7 accommodates the spin chuck 3 and the substrate W held by the spin chuck 3. The cup 7 collects a treatment liquid scattered from the rotating substrate W. An upper surface of the cup 7 has a cup opening 16 having a size that allows the substrate W in the horizontal posture and the spin chuck 3 to pass therethrough. The cup opening 16 is formed in a circular shape.

The cup 7 or the guard container 9 includes a drain 7A and an exhaust port 7B. The drain 7A drains the treatment liquid recovered by the cup 7 to an outside of the housing 11. The exhaust port 7B exhausts gas in the cup 7. The drain 7A may drain the treatment liquid recovered by each of the cup 7 and the guard container 9. In addition, the exhaust port 7B may exhaust an inside of the cup 7 and an inside of the guard container 9. An exhaust pipe 7C connected to the exhaust port 7B is provided with a pump 7D for exhausting gas.

The guard container 9 is a cylindrical container centered on the vertical axis AX1. The guard container 9 accommodates the substrate W, the spin chuck 3, and the cup 7. The guard container 9 includes a side wall 17 and a guard opening 19. The side wall 17 is formed in a cylindrical shape. The side wall 17 surrounds the spin chuck 3 and the side of the substrate W held by the spin chuck 3.

The side wall 17 includes a side wall body 17A and a ceiling wall 17B. The side wall body 17A is formed in a cylindrical shape. The ceiling wall 17B expands in an annular plate shape radially inward from an upper portion of the side wall body 17A. The guard opening 19 is formed by an upper portion of the side wall 17, that is, an inner peripheral edge of the ceiling wall 17B. The guard opening 19 is formed in a circular shape. The guard opening 19 is formed in a size that allows the substrate W in the horizontal posture and the spin chuck 3 to pass therethrough. The guard container 9 is coupled to the shielding plate 21 to be described later, and a peripheral region of a coupling portion is sealed. Details of this point will be described later.

The guard lifting and lowering mechanism 10 moves the cup 7 and the guard container 9 in a vertical direction Z. The guard lifting and lowering mechanism 10 includes, for example, an air cylinder or a linear actuator. The linear actuator includes an electric motor and includes, for example, a screw shaft or a belt.

As shown in FIG. 1, the guard lifting and lowering mechanism 10 lifts the cup 7 and the guard container 9 to an upper position H1. As a result, the guard container 9 can be fitted to the shielding plate 21 to be described later. In addition, the substrate W held by the spin chuck 3 can be accommodated in the guard container 9. As shown in FIG. 2, the guard lifting and lowering mechanism 10 lowers the cup 7 and the guard container 9 to a lower position H2. As a result, the substrate W held by the spin chuck 3 can be taken out from the cup 7 and the guard container 9 through the guard opening 19.

### 1-1. Outline of shielding plate and rotation nozzle plate

The substrate processing apparatus 1 further includes the shielding plate 21, the rotation nozzle plate 23, and a nozzle lifting and lowering mechanism 25 in the housing 11. The shielding plate 21 and the rotation nozzle plate 23 are provided above the substrate W held by the spin chuck 3. The shielding plate 21 and the rotation nozzle plate 23 can close the guard opening 19. The shielding plate 21 and the rotation nozzle plate 23 are each formed in a disk shape. The shielding plate 21 has a mounting hole 27 penetrating the shielding plate 21 in the vertical direction Z.

The rotation nozzle plate 23 is disposed in the mounting hole 27. A lower surface of the rotation nozzle plate 23 faces an upper surface of the substrate W held by the spin chuck 3. The rotation nozzle plate 23 is rotatable about a vertical axis AX2 with respect to the shielding plate 21. The vertical axis AX2 is arranged at a position different from the vertical axis AX1 in plan view.

The nozzle lifting and lowering mechanism 25 moves the shielding plate 21 and the rotation nozzle plate 23 in the vertical direction Z. In other words, the nozzle lifting and lowering mechanism 25 moves at least the rotation nozzle plate 23 in the vertical direction Z. The nozzle lifting and lowering mechanism 25 includes a rotation shaft 29, an arm 31, and a lifting and lowering mechanism body 33. A lower end of the rotation shaft 29 is fixed to an upper surface of the rotation nozzle plate 23. A distal end portion of the arm 31 rotatably supports an upper end portion of the rotation shaft 29 about the vertical axis AX2. As a result, the rotation nozzle plate 23 is rotatable about the vertical axis AX2 with respect to the arm 31.

An upper end of the lifting and lowering mechanism body 33 is fixed to a proximal end portion of the arm 31. The lifting and lowering mechanism body 33 moves the arm 31 in the vertical direction Z. In other words, the lifting and lowering mechanism body 33 moves the shielding plate 21 and the rotation nozzle plate 23 in the vertical direction Z via the rotation shaft 29 and the arm 31. The lifting and lowering mechanism body 33 includes an air cylinder or a linear actuator.

### 1-2. Fitting (attaching and detaching) structure between shielding plate and rotation nozzle plate

In FIG. 2, the shielding plate 21 and the rotation nozzle plate 23 are lifted and lowered integrally. On the other hand, in FIG. 1, the rotation nozzle plate 23 is separated from the shielding plate 21. That is, the shielding plate 21 is attached to the rotation nozzle plate 23 and is detached from the rotation nozzle plate 23. This structure will be described.

Reference is made to FIGS. 1 and 3. The rotation nozzle plate 23 includes a supporting member 35 that supports the shielding plate 21. On the other hand, the shielding plate 21 includes a supported member 37 supported by the supporting member 35. An upper surface of the supporting member 35 faces a lower surface of the supported member 37. For example, the supporting member 35 expands in an annular plate shape radially outward from an upper portion of the rotation nozzle plate 23. The supported member 37 is formed in, for example, an annular plate shape. The supported member 37 is provided on an upper surface of the shielding plate 21 with a cylindrical spacer 38 interposed therebetween.

The rotation nozzle plate 23 is fitted to the shielding plate 21. The shielding plate 21 and the rotation nozzle plate 23 include a plurality of pairs (for example, four pairs) of fitting members 39 and 41. The plurality of pairs of fitting members 39 and 41 are disposed at equal angular intervals around the vertical axis AX2.

For example, the four fitting members 39 are provided on the upper surface of the supporting member 35, and the four fitting members 41 are provided on the lower surface of the supported member 37. Each fitting member 39 is a fitting pin, and each fitting member 41 is a fitting hole. This may be reversed. That is, each fitting member 39 may be a fitting hole, and each fitting member 41 may be a fitting pin.

The four fitting members 39 (for example, fitting pins) of the supporting member 35 are respectively fitted to the four fitting members 41 (for example, fitting holes) of the supported member 37. Thus, the shielding plate 21 and the rotation nozzle plate 23 can be lifted and lowered integrally. The shielding plate 21 and the rotation nozzle plate 23 are integrally rotatable about the vertical axis AX2.

Such a fitting structure is configured as follows. As shown in FIG. 2, when the supporting member 35 of the rotation nozzle plate 23 supports the shielding plate 21, the rotation nozzle plate 23 is configured to lift and lower integrally with the shielding plate 21. As shown in FIG. 1, when the shielding plate 21 is supported on an upper portion of the guard container 9, the rotation nozzle plate 23 is configured to be separated from the shielding plate 21. The rotation nozzle plate 23 can be integrated with the shielding plate 21 or separated from the shielding plate 21.

### 1-3. Fitting structure between shielding plate and guard container

As shown in FIG. 1, the shielding plate 21 is fitted to the guard container 9. The guard container 9 and the shielding plate 21 include a plurality of pairs (for example, four pairs) of fitting members 43 and 45. The plurality of pairs of fitting members 43 and 45 are disposed at equal angular intervals around the vertical axis AX1.

Each fitting member 43 is provided on an upper surface of the side wall 17 of the guard container 9. Specifically, each fitting member 43 is formed on an upper surface of the ceiling wall 17B. Each fitting member 45 is provided on a lower surface of a peripheral edge portion of the shielding plate 21. Each fitting member 43 is a fitting pin, and each fitting member 45 is a fitting hole. This may be reversed. That is, each fitting member 43 may be a fitting hole, and each fitting member 45 may be a fitting pin.

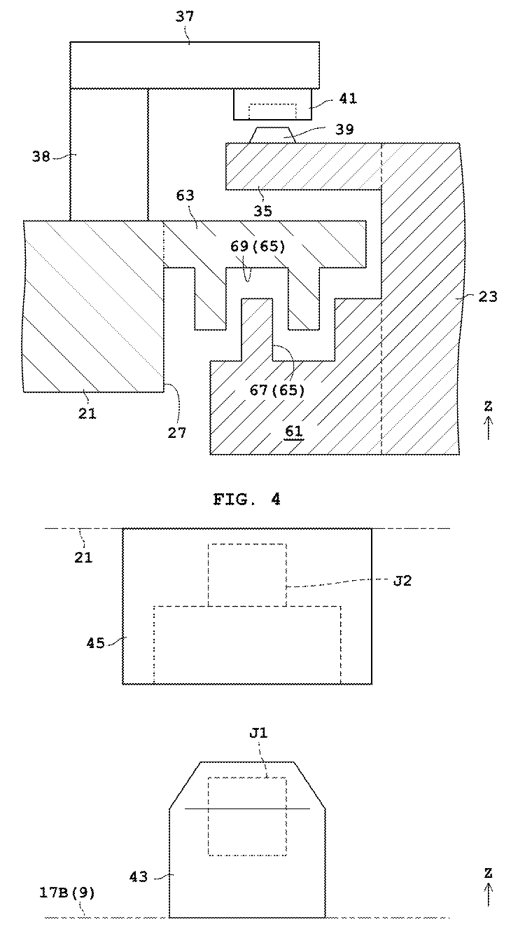

FIG. 4 is a diagram showing a fitting structure of the guard container 9 and the shielding plate 21. The fitting member 43 is configured to be attracted to the fitting member 45 by magnetic force. That is, the fitting members 43 and 45 have magnets J1 and J2, respectively. For example, the magnet J1 is embedded in the fitting member 43 (fitting pin). The magnet J2 is embedded in the fitting member 45 (fitting hole). The magnet J2 is disposed in a depth of the hole of the fitting member 45. As a result, the fitting member 43 is guided to the hole of the fitting member 45, and a resistance force is generated so that the fitting member 43 does not come off from the hole of the fitting member 45. Each of the magnets J1 and J2 is a permanent magnet, but may be an electromagnet. Further, one of the pair of fitting members 43 and 45 may have a ferromagnet attached to a magnet, such as iron, instead of the magnet.

The four fitting members 45 (fitting holes) are respectively fitted to the four fitting members 43 (fitting pins). Thus, the shielding plate 21 can be integrated with the guard container 9. The guard container 9 is configured not to be rotated about each of the two vertical axes AX1 and AX2. Therefore, the shielding plate 21 fitted to the guard container 9 is also not rotated about each of the two vertical axes AX1 and AX2.

### 1-4. Labyrinth seal between guard container and shielding plate

Reference is made to FIG. 5. The upper portion of the guard container 9 and the lower surface of the peripheral edge portion of the shielding plate 21 have a labyrinth seal 47. As a result, it is possible to suppress outside air from entering an internal space SP from between the guard container 9 and the shielding plate 21. Specific description will be given. The labyrinth seal 47 includes a first uneven portion 49 and a second uneven portion 51.

On the upper surface of the ceiling wall 17B of the guard container 9, the first uneven portion 49 in which circular recesses and circular protrusions are concentrically and alternately disposed is provided. The first uneven portion 49 includes one or more recesses and a plurality of protrusions. Similarly, on the lower surface of the peripheral edge portion of the shielding plate 21, the second uneven portion 51 in which circular protrusions and circular recesses are concentrically and alternately disposed is provided. The second uneven portion 51 includes a plurality of protrusions and one or more recesses.

When the shielding plate 21 is supported on the upper portion of the guard container 9, that is, when the shielding plate 21 is fitted to the guard container 9, the first uneven portion 49 and the second uneven portion 51 are disposed with a gap GP1 (flow path) interposed therebetween. At this time, the protrusions of the first uneven portion 49 and the protrusions of the second uneven portion 51 are alternately disposed. The protrusion of the first uneven portion 49 is accommodated in the recess of the second uneven portion 51.

The substrate processing apparatus 1 further includes a first inert gas supply mechanism 53. The first inert gas supply mechanism 53 supplies an inert gas such as nitrogen to the labyrinth seal 47. Further, the first inert gas supply mechanism 53 supplies the inert gas into the internal space SP surrounded by the guard container 9, the shielding plate 21, and the rotation nozzle plate 23 via the labyrinth seal 47.

The first inert gas supply mechanism 53 includes a discharge port 55, a gas pipe 57, and an on-off valve V1. The discharge port 55 is provided, for example, in the recess between the two adjacent protrusions in the second uneven portion 51 of the shielding plate 21. The discharge port 55 may be provided in the recess of the first uneven portion 49 of the guard container 9 indicated by an arrow AR1 in FIG. 5. The discharge port 55 may be provided in both the first uneven portion 49 and the second uneven portion 51.

The gas pipe 57 connects the discharge port 55 and a first inert gas supply source 59. The on-off valve V1 is provided in the gas pipe 57. The on-off valve V1 selectively supplies an inert gas from the first inert gas supply source 59 and stops the supply of the inert gas.

When the on-off valve V1 is opened, the inert gas is supplied from the discharge port 55 to the labyrinth seal 47 (that is, the gap GP1 between the first uneven portion 49 and the second uneven portion 51). As a result, the internal space SP can be filled with the inert gas via the labyrinth seal 47 while enhancing airtightness of the labyrinth seal 47. Specifically, the gap GP1 is filled with the inert gas, and the inert gas is pushed out from the gap GP1 to the internal space SP and an outside (an outside of the internal space SP) (arrows AR2 and AR3). As a result, gas and liquid are suppressed from entering the labyrinth seal 47 (gap GP1) from the internal space SP and the outside. In addition, since the internal space SP is filled with the inert gas, oxygen in the air in the internal space SP is reduced.

### 1-5. Labyrinth seal between shielding plate and rotation nozzle plate

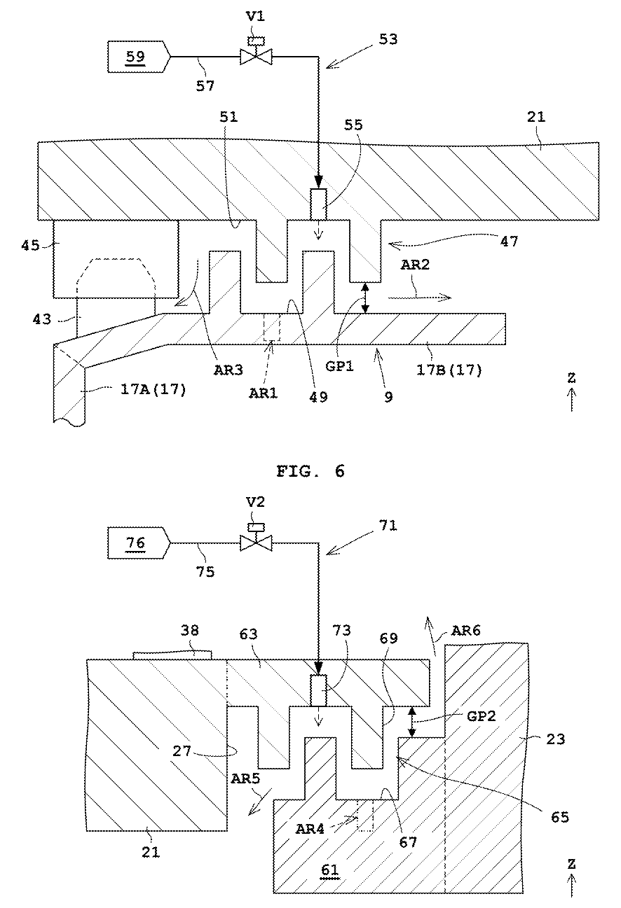

Reference is made to FIG. 6. The rotation nozzle plate 23 has a flange 61 protruding to an outer peripheral side. On the other hand, the shielding plate 21 has an annular portion 63 protruding to the mounting hole 27. An upper surface of the flange 61 and a lower surface of the annular portion 63 have a labyrinth seal 65. As a result, it is possible to suppress outside air from entering the internal space SP from between the shielding plate 21 and the rotation nozzle plate 23. Specific description will be given. The labyrinth seal 65 includes a third uneven portion 67 and a fourth uneven portion 69.

On the upper surface of the flange 61, the third uneven portion 67 in which circular recesses and circular protrusions are concentrically and alternately disposed is provided. The third uneven portion 67 includes one or more recesses and one or more protrusions. Similarly, on the lower surface of the annular portion 63, the fourth uneven portion 69 in which circular protrusions and circular recesses are concentrically and alternately disposed is provided. The fourth uneven portion 69 includes a plurality of protrusions and one or more recesses.

When the rotation nozzle plate 23 is located at a processing position H3 (see FIG. 1), the third uneven portion 67 and the fourth uneven portion 69 are disposed with a gap GP2 (flow path) interposed therebetween. At this time, the protrusions of the third uneven portion 67 and the protrusions of the fourth uneven portion 69 are alternately disposed.

The substrate processing apparatus 1 further includes a second inert gas supply mechanism 71. The second inert gas supply mechanism 71 supplies an inert gas such as nitrogen to the labyrinth seal 65. Further, the second inert gas supply mechanism 71 supplies the inert gas into the internal space SP surrounded by the guard container 9, the shielding plate 21, and the rotation nozzle plate 23 via the labyrinth seal 65.

The second inert gas supply mechanism 71 includes a discharge port 73, a gas pipe 75, and an on-off valve V2. The discharge port 73 is provided, for example, in the recess between the two adjacent protrusions in the fourth uneven portion 69 of the shielding plate 21. The discharge port 73 may be provided in the recess of the third uneven portion 67 of the rotation nozzle plate 23 indicated by an arrow AR4 in FIG. 6. The discharge port 73 may be provided on both the third uneven portion 67 and the fourth uneven portion 69.

The gas pipe 75 connects the discharge port 73 and a second inert gas supply source 76. The on-off valve V2 is provided in the gas pipe 75. The on-off valve V2 selectively supplies an inert gas from the second inert gas supply source 76 and stops the supply of the inert gas.

When the on-off valve V2 is opened, the inert gas is supplied from the discharge port 73 to the labyrinth seal 65 (gap GP2). As a result, the gap GP2 is filled with the inert gas, and the inert gas is pushed out from the gap GP2 to the internal space SP and the outside (the outside of the internal space SP) (arrows AR5 and AR6). As a result, gas and liquid are suppressed from entering the labyrinth seal 65 (gap GP2) from the internal space SP and the outside. In addition, since the internal space SP is filled with the inert gas, oxygen in the air in the internal space SP is reduced.

### 1-6. Nozzle and nozzle rotation mechanism

Reference is made to FIGS. 1 and 2. The substrate processing apparatus 1 further includes a single nozzle NZ1 and a nozzle rotation mechanism 78 inside the housing 11. The nozzle NZ1 is provided at a position away from the vertical axis AX2 in the rotation nozzle plate 23. The nozzle NZ1 discharges a treatment liquid and an inert gas to the substrate W held by the spin chuck 3.

FIG. 7 is a diagram showing a lower surface of the single nozzle NZ1. The nozzle NZ1 includes a plurality of (for example, five) discharge openings 81A, 81B, 81C, 81D, and 81E. Each of the plurality of discharge openings 81A to 81E discharges at least one of the treatment liquid and the inert gas. For example, the discharge opening 81A among the plurality of discharge openings 81A to 81E discharges a chemical liquid as the treatment liquid. The discharge opening 81B discharges a rinsing liquid as the treatment liquid. The discharge opening 81C discharges an organic solvent as the treatment liquid. The discharge opening 81D discharges the inert gas such as nitrogen. The discharge opening 81E discharges both the treatment liquid and the inert gas. In other words, the discharge opening 81E sprays the treatment liquid by mixing the treatment liquid and the inert gas.

As the chemical liquid, for example, diluted aqueous ammonia (dNH₄OH) or diluted hydrofluoric acid (dHF) is used. As the rinsing liquid, for example, pure water such as deionized water (DIW) is used. As the organic solvent, for example, isopropyl alcohol (IPA) is used. The discharge opening 81E sprays the treatment liquid such as DIW, for example. The number of discharge openings 81A to 81E is not limited to five.

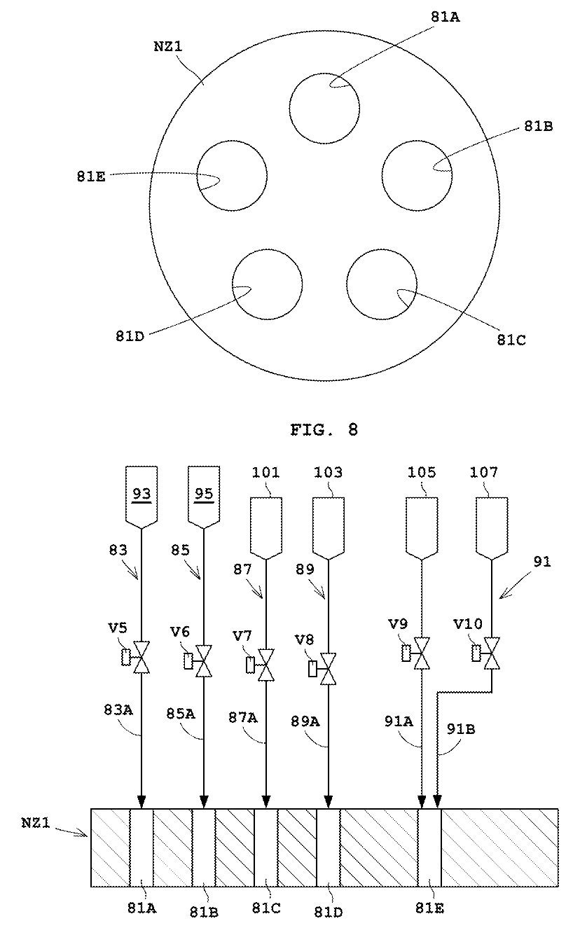

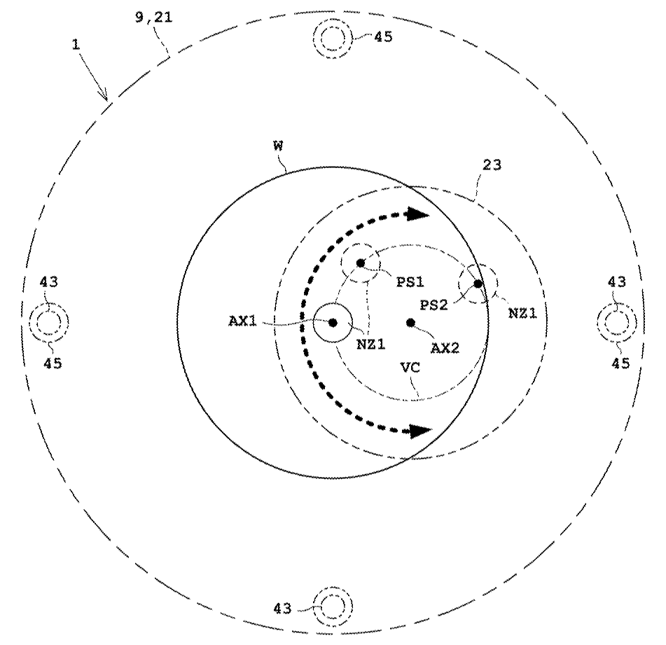

FIG. 8 is a diagram showing a configuration for supplying a treatment liquid and an inert gas to the nozzle NZ1. The substrate processing apparatus 1 includes a chemical liquid supply mechanism 83, a rinsing liquid supply mechanism 85, a solvent supply mechanism 87, a third inert gas supply mechanism 89, and a two-fluid supply mechanism 91.

The chemical liquid supply mechanism 83 includes a chemical liquid pipe 83A, an on-off valve V5, and a first pump. The chemical liquid pipe 83A connects the discharge opening 81A and a chemical liquid supply source 93. The on-off valve V5 and the first pump are provided in the chemical liquid pipe 83A. The first pump sends a chemical liquid from the chemical liquid supply source 93 to the discharge opening 81A. The on-off valve V5 selectively supplies the chemical liquid and stops the supply of the chemical liquid.

The rinsing liquid supply mechanism 85 includes a rinsing liquid pipe 85A, an on-off valve V6, and a second pump. The rinsing liquid pipe 85A connects the discharge opening 81B and a rinsing liquid supply source 95. The on-off valve V6 and the second pump are provided in the rinsing liquid pipe 85A. The second pump sends a rinsing liquid from the rinsing liquid supply source 95 to the discharge opening 81B. The on-off valve V6 selectively supplies the rinsing liquid and stops the supply of the rinsing liquid.

The solvent supply mechanism 87 includes a solvent pipe 87A, an on-off valve V7, and a third pump. The solvent pipe 87A connects the discharge opening 81C and a solvent supply source 101. The on-off valve V7 and the third pump are provided in the solvent pipe 87A. The third pump sends an organic solvent from the solvent supply source 101 to the discharge opening 81C. The on-off valve V7 selectively supplies the organic solvent and stops the supply of the organic solvent.

The third inert gas supply mechanism 89 includes a gas pipe 89A and an on-off valve V8. The gas pipe 89A connects the discharge opening 81D and a third inert gas supply source 103. The on-off valve V8 is provided in the gas pipe 89A. The on-off valve V8 selectively supplies an inert gas from the third inert gas supply source 103 and stops the supply of the inert gas.

The two-fluid supply mechanism 91 includes a treatment liquid pipe 91A, a gas pipe 91B, two on-off valves V9 and V10, and a fourth pump. The treatment liquid pipe 91A connects the discharge opening 81E and a treatment liquid supply source 105. The on-off valve V9 and the fourth pump are provided in the treatment liquid pipe 91A. The fourth pump sends a treatment liquid from the treatment liquid supply source 105 to the discharge opening 81E. The gas pipe 91B connects the discharge opening 81E and a fourth inert gas supply source 107. The on-off valve V10 is provided in the gas pipe 91B. The two on-off valves V9 and V10 selectively supply an inert gas from the fourth inert gas supply source 107 and the treatment liquid and stop the supply thereof. That is, when the two on-off valves V9 and V10 are opened, the treatment liquid is sprayed.

In principle, the treatment liquid supplied to the nozzle NZ1 is assumed to have an oxygen concentration in the liquid below a preset threshold, by supplying and bubbling the inert gas into the treatment liquid stored in a tank, for example.

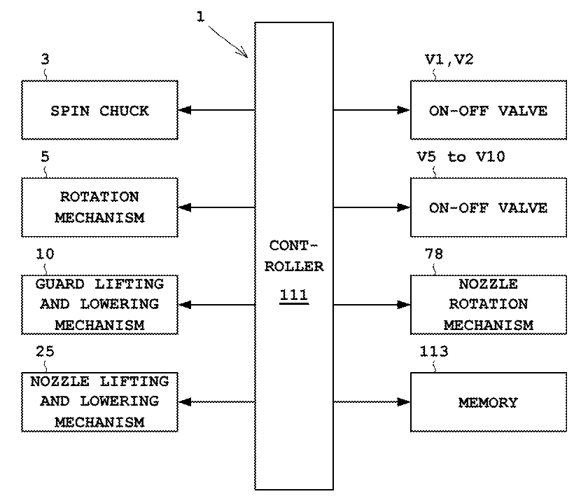

Reference is made to FIGS. 1 and 9. FIG. 9 is a plan view showing an arrangement of the substrate W, the shielding plate 21, the rotation nozzle plate 23, and the nozzle NZ1. As shown in FIG. 9, the nozzle NZ1 is provided on a virtual circle VC with the vertical axis AX2 as a central axis in the rotation nozzle plate 23. The virtual circle VC is a trajectory of the nozzle NZ1. The virtual circle VC passes through the center of the substrate W held by the spin chuck 3 in plan view. As shown in FIG. 9, the nozzle NZ1 can be moved to the center of the substrate W in plan view. When the nozzle NZ1 is located at the center of the substrate W, the nozzle NZ1 can discharge at least one of the treatment liquid and the inert gas to the center of the substrate W.

The nozzle rotation mechanism 78 rotates the rotation nozzle plate 23 about the vertical axis AX2 via the rotation shaft 29. However, since the chemical liquid pipe 83A and the like are connected to the upper surface of the rotation nozzle plate 23, the nozzle rotation mechanism 78 does not continue to rotate the rotation nozzle plate 23 only in one direction. That is, the nozzle rotation mechanism 78 swings the rotation nozzle plate 23 within a preset angular range (for example, +180 degrees to -180 degrees). In other words, the nozzle rotation mechanism 78 rotates the rotation nozzle plate 23 clockwise at a preset angle (for example, 180 degrees), and rotates the rotation nozzle plate 23 counterclockwise at a preset angle (for example, 180 degrees). Note that the preset angle may be 180 degrees or more. The nozzle rotation mechanism 78 includes an electric motor. The nozzle rotation mechanism 78 may include a belt and a pulley.

The nozzle rotation mechanism 78 is configured to move the nozzle NZ1 between the center of the substrate W and a peripheral edge of the substrate W in plan view by rotating the rotation nozzle plate 23 about the vertical axis AX2. A diameter of the virtual circle VC is substantially the same as a radius of the substrate W. The plurality of discharge openings 81A to 81E can be moved along with the movement of the nozzle NZ1.

For example, it is assumed that the nozzle NZ1 is located at the center of the substrate W. An angle around the vertical axis AX2 at this time is zero degrees. The nozzle rotation mechanism 78 rotates the nozzle NZ1 (rotation nozzle plate 23) clockwise by, for example, 50 degrees about the vertical axis AX2. As a result, the nozzle NZ1 can discharge the treatment liquid or the like to a middle position PS1 in the middle between the center of the substrate W and the peripheral edge of the substrate W.

Further, for example, it is assumed that the nozzle NZ1 is located at the center of the substrate W. The nozzle rotation mechanism 78 rotates the nozzle NZ1 (rotation nozzle plate 23) clockwise by, for example, 150 degrees to 180 degrees about the vertical axis AX2. As a result, the nozzle NZ1 can discharge the treatment liquid or the like to a position PS2 of a peripheral edge portion of the substrate W.

### 1-7. Configuration related to control

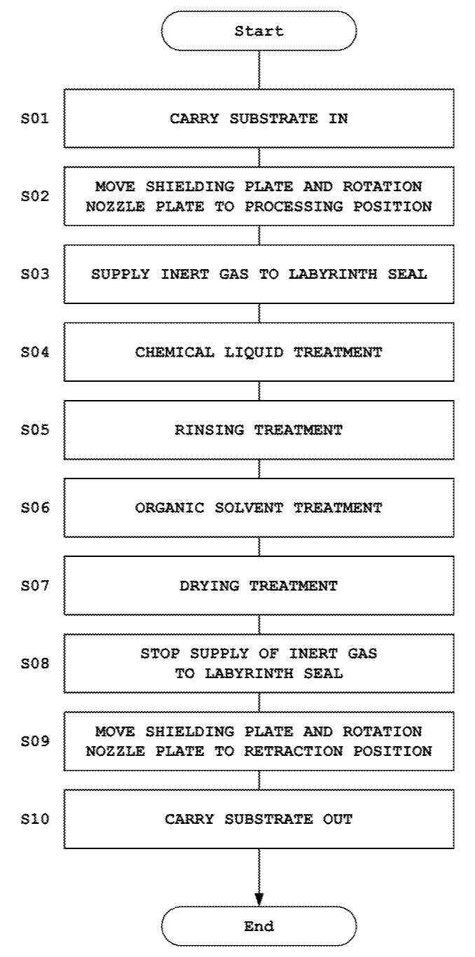

Reference is made to FIG. 10. The substrate processing apparatus 1 includes a controller 111 and a memory 113. The controller 111 controls each component of the substrate processing apparatus 1. The controller 111 controls, for example, the spin chuck 3, the rotation mechanism 5, the guard lifting and lowering mechanism 10, the nozzle lifting and lowering mechanism 25, the nozzle rotation mechanism 78, and the on-off valves V1, V2, and V5 to V10.

The controller 111 includes one or more processors such as, for example, a central processing unit (CPU). The memory 113 is also referred to as a storage medium. The memory 113 includes, for example, at least one of a read-only memory (ROM), a random-access memory (RAM), and a hard disk. The memory 113 stores computer programs and parameters necessary for controlling each component of the substrate processing apparatus 1. The controller 111 reads necessary information (for example, parameters) from the memory 113.

The spin chuck 3 corresponds to a chuck of the present invention. The vertical axis AX1 corresponds to a first vertical axis of the present invention. The vertical axis AX2 corresponds to a second vertical axis of the present invention. The fitting member 39 is referred to as a nozzle side fitting member. The fitting member 41 is referred to as a plate-side fitting member. The fitting member 43 corresponds to a guard-side fitting member of the present invention. The fitting member 45 corresponds to a plate-side fitting member of the present invention. The first inert gas supply mechanism 53 and the second inert gas supply mechanism 71 each correspond to an inert gas supply mechanism of the present invention. The discharge opening 81D and the third inert gas supply mechanism 89 correspond to an inert gas supply mechanism of the present invention.

### 2. Operation of substrate processing apparatus

Next, an example of an operation of the substrate processing apparatus 1 will be described with reference to FIG. 11.

### Step S01 Carrying-in of substrate

The substrate processing apparatus 1 is in a state shown in FIG. 2. That is, the shielding plate 21 and the rotation nozzle plate 23 are located at a retraction position H4 (non-processing position), and the cup 7 and the guard container 9 are located at the lower position H2. A transfer robot (not shown) causes a hand holding the substrate W to enter the housing 11, and then transfers the substrate W to the spin chuck 3. The spin chuck 3 holds the substrate W. The transfer robot retracts the hand from an inside of the housing 11.

### Step S02 Movement of shielding plate and rotation nozzle plate to processing position

Thereafter, the guard lifting and lowering mechanism 10 lifts the cup 7 and the guard container 9 from the lower position H2 to the upper position H1. As a result, the cup 7 and the guard container 9 accommodate the substrate W held by the spin chuck 3.

Thereafter, the nozzle lifting and lowering mechanism 25 lowers the shielding plate 21 and the rotation nozzle plate 23 from the retraction position H4. When the shielding plate 21 is placed on the upper portion of the guard container 9, for example, the four fitting members 45 of the shielding plate 21 are respectively fitted to the four fitting members 43 of the guard container 9. As a result, the gap GP1 of the labyrinth seal 47 becomes a preset distance.

Thereafter, the nozzle lifting and lowering mechanism 25 further lowers the rotation nozzle plate 23 to the processing position H3 with respect to the shielding plate 21 placed on the upper portion of the guard container 9. That is, the nozzle rotation mechanism 25 further lowers only the rotation nozzle plate 23 out of the shielding plate 21 and the rotation nozzle plate 23. As a result, the four fitting members 39 of the rotation nozzle plate 23 are respectively detached from, for example, the four fitting members 41 of the shielding plate 21. In other words, the rotation nozzle plate 23 is detached from the shielding plate 21. As a result, the rotation nozzle plate 23 can be rotated about the vertical axis AX2 with respect to the shielding plate 21. In addition, the gap GP2 of the labyrinth seal 65 becomes a preset distance. Thus, the substrate processing apparatus 1 enters a state shown in FIG. 1.

### Step S03 Supply of inert gas to labyrinth seal

Thereafter, the two on-off valves V1 and V2 are opened. When the on-off valve V1 is opened, the inert gas is discharged from the discharge port 55 shown in FIG. 5. As a result, the gap GP1 is filled with the inert gas, and entry of liquid and gas into the gap GP1 (labyrinth seal 47) is suppressed. The inert gas discharged from the discharge port 55 is supplied into the internal space SP via the labyrinth seal 47.

When the on-off valve V2 is opened, the inert gas is discharged from the discharge port 73 shown in FIG. 6. As a result, the gap GP2 (labyrinth seal 65) is filled with the inert gas, and entry of liquid and gas into the gap GP2 (labyrinth seal 65) is suppressed. The inert gas discharged from the discharge port 73 is supplied into the internal space SP via the labyrinth seal 65. Gas in the internal space SP and the like is exhausted from the exhaust port 7B. As a result, an inside of the internal space SP is maintained at a pressure lower than the atmospheric pressure. As a result, oxygen in the air in the internal space SP is reduced. The open states of the two on-off valves V1 and V2 and the exhaust from the exhaust port 7B are continued until step S08.

### Step S04 Chemical liquid treatment

As shown in FIG. 1, the nozzle NZ1 is positioned above the center of the substrate W held by the spin chuck 3. Further, the rotation mechanism 5 rotates the substrate W held by the spin chuck 3 about the vertical axis AX1. Then, the on-off valve V5 is opened. As a result, the chemical liquid (for example, dNH₄OH) is discharged from the discharge opening 81A of the nozzle NZ1. The chemical liquid that has arrived at the upper surface of the substrate W is spread over the entire upper surface of the substrate W by the rotation of the substrate W, and the excess chemical liquid is scattered to an outside of the substrate W.

The nozzle rotation mechanism 78 rotates the rotation nozzle plate 23 about the vertical axis AX2. As a result, it is possible to move the nozzle NZ1 between the center of the rotating substrate W and the peripheral edge portion of the substrate W in plan view while discharging the chemical liquid. As a result, the chemical liquid can be supplied to each position of the substrate W from directly above. Therefore, it is possible to suppress non-uniform chemical liquid treatment.

When the discharge of the chemical liquid from the discharge opening 81A is stopped, the on-off valve V5 is closed. The nozzle rotation mechanism 78 moves the nozzle NZ1 to the center of the substrate W in plan view. Further, the rotation mechanism 5 continues the rotation of the substrate W until a drying treatment in step S07.

### Step S05 Rinsing treatment

Thereafter, the on-off valve V6 is opened. As a result, the rinsing liquid (for example, DIW) is discharged from the discharge opening 81B of the nozzle NZ1. The chemical liquid on the upper surface of the substrate W is replaced with the rinsing liquid. The excess rinsing liquid is scattered to the outside of the substrate W. The nozzle rotation mechanism 78 rotates the rotation nozzle plate 23 about the vertical axis AX2. As a result, the nozzle NZ1 can be moved between the center of the rotating substrate W and the peripheral edge portion of the substrate W in plan view while discharging the rinsing liquid.

When the discharge of the rinsing liquid from the discharge opening 81B is stopped, the on-off valve V6 is closed. The nozzle rotation mechanism 78 moves the nozzle NZ1 to the center of the substrate W in plan view.

### Step S06 Organic solvent treatment

Thereafter, the on-off valve V7 is opened. As a result, the organic solvent (for example, IPA) is discharged from the discharge opening 81C of the nozzle NZ1. The rinsing liquid on the upper surface of the substrate W is replaced with the organic solvent. In addition, the excess organic solvent is scattered to the outside of the substrate W. The nozzle rotation mechanism 78 rotates the rotation nozzle plate 23 about the vertical axis AX2. As a result, the nozzle NZ1 can be moved between the center of the rotating substrate W and the peripheral edge portion of the substrate W in plan view while discharging the organic solvent.

When the discharge of the organic solvent from the discharge opening 81C is stopped, the on-off valve V7 is closed. The nozzle rotation mechanism 78 moves the nozzle NZ1 to the center of the substrate W in plan view.

### Step S07 Drying treatment

Thereafter, the on-off valve V8 is opened. As a result, the inert gas is discharged from the discharge opening 81D of the nozzle NZ1 toward the center of the substrate W. When the inert gas hits the center of the substrate W, a liquid film of the organic solvent in a central region of the upper surface of the substrate W is pushed away, and an opening 121 is formed in the liquid film (see FIG. 12). Thereafter, the on-off valve V8 is closed.

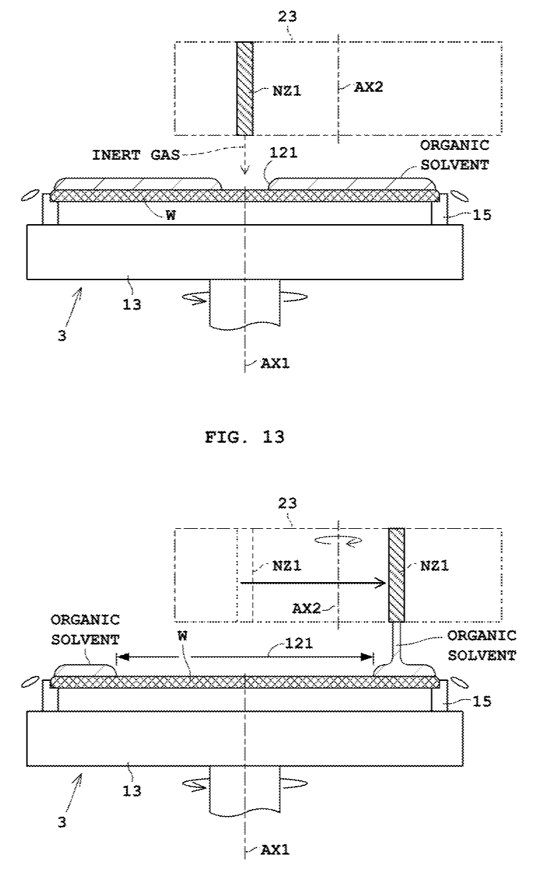

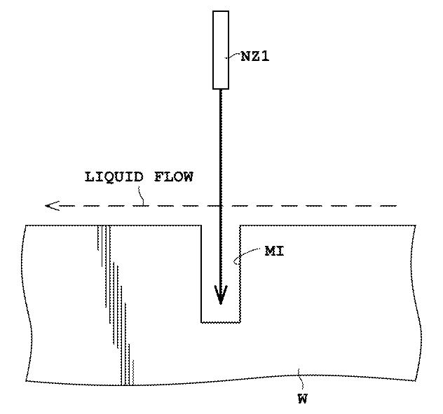

Thereafter, the opening 121 is enlarged by a centrifugal force due to the rotation of the substrate W. The nozzle rotation mechanism 78 moves the nozzle NZ1 so that a liquid arrival point of the organic solvent is set to an outside of the opening 121. Thereafter, the on-off valve V7 is opened. As a result, the organic solvent is discharged from the discharge opening 81C of the nozzle NZ1 (see FIG. 13). This makes it possible to suppress local elimination of the organic solvent on the upper surface of the substrate W on the outside of the opening 121. Following the enlargement of the opening 121 by the centrifugal force due to the rotation of the substrate W, the nozzle rotation mechanism 78 moves the nozzle NZ1 from the center side of the substrate W to the peripheral edge portion of the substrate W while causing the organic solvent to be discharged.

When the liquid arrival position of the organic solvent discharged from the discharge opening 81C reaches the peripheral edge portion of the substrate W, the on-off valve V7 is closed. As a result, the discharge of the organic solvent from the discharge opening 81C is stopped. Thereafter, the rotation mechanism 5 increases a rotation speed of the substrate W held by the spin chuck 3 to shake off the organic solvent of the substrate W. Thus, the substrate W is dried.

Thereafter, the rotation mechanism 5 stops the rotation of the substrate W. Thereafter, the spin chuck 3 releases the holding of the substrate W. Further, the nozzle rotation mechanism 78 returns the nozzle NZ1 to a preset position.

### Step S08 Stop supply of inert gas to labyrinth seal

Thereafter, for example, by stopping the pump 7D, the exhaust from the exhaust port 7B is stopped. The inert gases discharged from the discharge ports 55 and 73 return the inside of the internal space SP to the atmospheric pressure. Thereafter, the two on-off valves V1 and V2 are closed. As a result, the discharge of the inert gases from the discharge ports 55 and 73 is stopped.

### Step S09 Movement of shielding plate and rotation nozzle plate to retraction position

Thereafter, the nozzle lifting and lowering mechanism 25 lifts the rotation nozzle plate 23 from the processing position H3. At this point, only the rotation nozzle plate 23 out of the shielding plate 21 and the rotation nozzle plate 23 lifts. During the lifting, the four fitting members 39 of the rotation nozzle plate 23 are respectively fitted to the four fitting members 41 of the shielding plate 21. Accordingly, the shielding plate 21 and the rotation nozzle plate 23 are integrally lifted. Then, the nozzle lifting and lowering mechanism 25 lifts the shielding plate 21 and the rotation nozzle plate 23 to the retraction position H4 while releasing fitted states of the four pairs of fitting members 43 and 45.

Thereafter, the guard lifting and lowering mechanism 10 lowers the cup 7 and the guard container 9 from the upper position H1 to the lower position H2. As a result, the substrate W on the spin chuck 3 is taken out from the guard container 9 and the like through the guard opening 19. As a result, the substrate processing apparatus 1 enters the state shown in FIG. 2.

### Step S10 Carrying-out of substrate

The transfer robot (not shown) receives the substrate W from the spin chuck 3 and transfers the substrate W to the next destination.

According to the present embodiment, the shielding plate 21 closes the guard opening 19 of the guard container 9, and the inert gas is supplied to the internal space SP surrounded by the guard container 9 and the shielding plate 21. The rotation nozzle plate 23 is disposed in the mounting hole 27 penetrating the shielding plate 21 in the vertical direction Z. The rotation nozzle plate 23 is rotatable with respect to the shielding plate 21 about the vertical axis AX2 arranged at a position different from the vertical axis AX1 passing through the center of the substrate W. The nozzle NZ1 is provided at a position away from the vertical axis AX2 in the rotation nozzle plate 23. The nozzle rotation mechanism 78 rotates the rotation nozzle plate 23 about the vertical axis AX2, so that the nozzle NZ1 moves about the vertical axis AX2. Therefore, nozzle scanning can be performed while reducing oxygen in the air in a small space.

Furthermore, since the nozzle scanning can be performed, in-plane uniformity in the processing can be enhanced. For example, as shown in FIG. 14, it is assumed that a groove pattern MI is formed on the upper surface of the substrate W. When the IPA flows from the center side of the substrate W along the upper surface of the substrate W, there is a possibility that the DIW in the groove pattern MI cannot be sufficiently replaced (see broken line arrow). In this regard, for example, the IPA is discharged from directly above the groove pattern MI by the nozzle scanning, so that replacement property of the DIW in the groove pattern MI can be improved.

### Second embodiment

Next, a second embodiment of the present invention will be described with reference to the drawings. Note that description common to the first embodiment will be omitted. FIG. 15 is a plan view showing a plurality of nozzles NZ1 to NZ5 provided in a rotation nozzle plate 23 according to the second embodiment.

In the first embodiment, the single nozzle NZ1 is provided in the rotation nozzle plate 23, and the plurality of discharge openings 81A to 81E are provided in the single nozzle NZ1. In this regard, in the second embodiment, the plurality of nozzles NZ1 to NZ5 may be provided in the rotation nozzle plate 23.

Reference is made to FIG. 15. The substrate processing apparatus 1 includes the plurality of (for example, five) nozzles NZ1 to NZ5 including the nozzle NZ1. Each of the plurality of nozzles NZ1 to NZ5 is provided at a position away from a vertical axis AX2 of the rotation nozzle plate 23. The plurality of nozzles NZ1 to NZ5 are preferably provided on a virtual circle VC with the vertical axis AX2 as a central axis in the rotation nozzle plate 23. In other words, the nozzles NZ1 to NZ5 preferably have the same distance to the vertical axis AX2. In addition, the virtual circle VC preferably passes through the center of a substrate W held by a spin chuck 3 in plan view.

Each of the plurality of nozzles NZ1 to NZ5 of the present embodiment is different from the nozzle NZ1 of the first embodiment, and includes a single discharge opening. At least one of the plurality of nozzles NZ1 to NZ5 may include a plurality of discharge openings. Each of the plurality of nozzles NZ1 to NZ5 is configured to discharge at least one of a treatment liquid and an inert gas to the substrate W held by the spin chuck 3.

For example, the nozzle NZ1 discharges a chemical liquid as the treatment liquid by a chemical liquid supply mechanism 83. The nozzle NZ2 discharges a rinsing liquid as the treatment liquid by a rinsing liquid supply mechanism 85. The nozzle NZ3 discharges an organic solvent as the treatment liquid by a solvent supply mechanism 87. The nozzle NZ4 discharges the inert gas such as nitrogen by a third inert gas supply mechanism 89. The nozzle NZ5 discharges both the treatment liquid and the inert gas by a two-fluid supply mechanism 91. In other words, the nozzle NZ5 sprays the treatment liquid by mixing the treatment liquid and the inert gas. That is, the nozzle NZ5 is a two-fluid nozzle.

A nozzle rotation mechanism 78 rotates the rotation nozzle plate 23 about the vertical axis AX2. As a result, the plurality of nozzles NZ1 to NZ5 can be integrally moved about the vertical axis AX2. Furthermore, for example, as shown in FIG. 15 (in plan view), the nozzle NZ4 can be moved instead of the nozzle NZ3 to the center position of the substrate W where the nozzle NZ3 is located.

According to the present embodiment, since the plurality of nozzles NZ1 to NZ5 are provided in the rotation nozzle plate 23, the plurality of nozzles NZ1 to NZ5 can be moved. In addition, since the plurality of nozzles NZ1 to NZ5 are provided on the virtual circle VC with the vertical axis AX2 as the central axis, trajectories of the plurality of nozzles NZ1 to NZ5 can be made the same. Since the virtual circle VC passes through the center of the substrate W in plan view, each of the plurality of nozzles can pass through the center of the substrate.

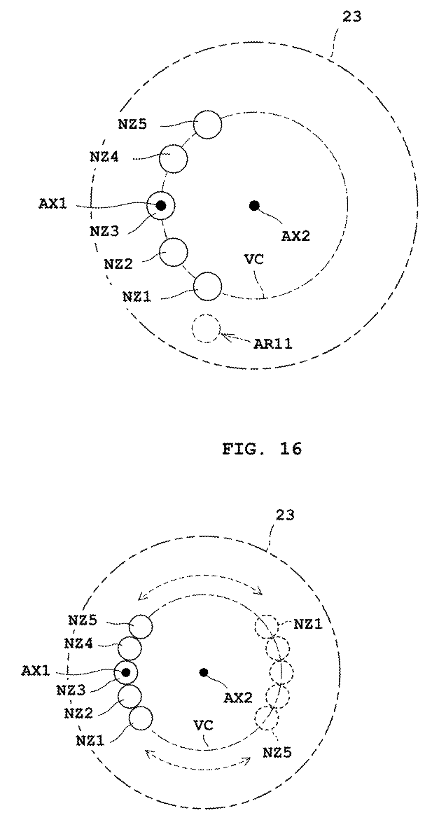

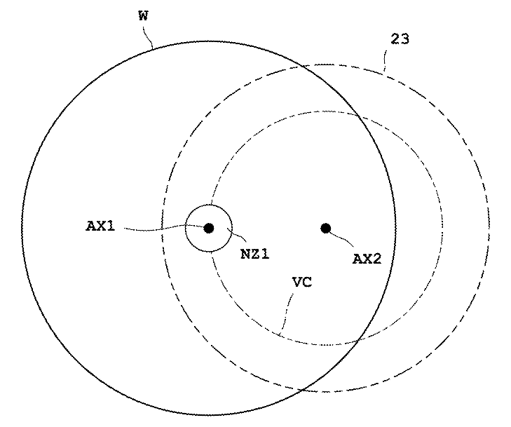

A modification of the present embodiment will be described. In the plurality of nozzles NZ1 to NZ5 shown in FIG. 15, an interval between two adjacent nozzles (for example, the nozzles NZ2 and NZ3) is relatively wide. In this regard, as shown in FIG. 16, for example, an interval between two adjacent nozzles (for example, the nozzles NZ2 and NZ3) may be narrowed. In FIG. 16, the two adjacent nozzles are in contact with each other.

Another modification of the present embodiment will be described. The plurality of nozzles NZ1 to NZ5 are disposed on the same virtual circle VC in the rotation nozzle plate 23. In this regard, as indicated by an arrow AR11 in FIG. 15, for example, the nozzle NZ1 may not be disposed on the virtual circle VC in which the other nozzles NZ2 to NZ5 are disposed. The nozzles NZ1 to NZ5 may have different distances to the vertical axis AX2.

### Third embodiment

Next, a third embodiment of the present invention will be described with reference to the drawings. Note that description common to the first and second embodiments will be omitted. FIG. 17 is a plan view showing a virtual circle VC in a rotation nozzle plate 23 according to the third embodiment, and a nozzle NZ1 provided on the virtual circle VC.

The virtual circles VC of the first and second embodiments are set in the region of the substrate W in plan view. In this regard, the virtual circle VC may pass through a position deviated from a substrate W held by a spin chuck 3 in plan view.

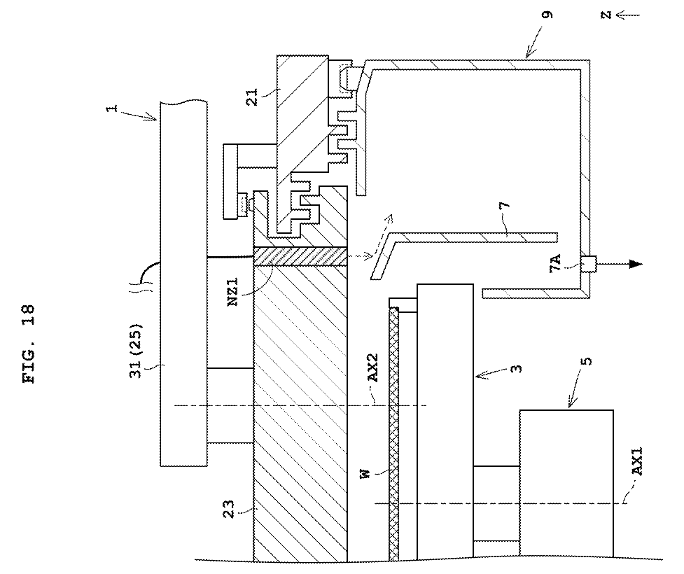

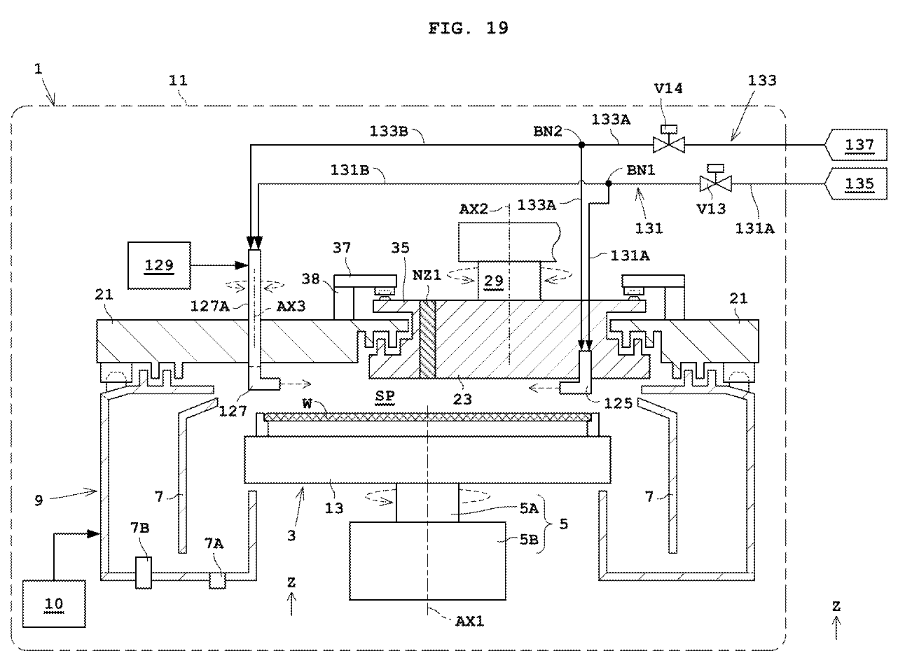

Reference is made to FIG. 17. For example, the virtual circle VC centered on a vertical axis AX2 passes through the center (vertical axis AX1) of the substrate W and passes through the position deviated from the substrate W in plan view. In this case, for example, a diameter of the virtual circle VC is larger than a radius of the substrate W. A nozzle rotation mechanism 78 rotates the rotation nozzle plate 23 about the vertical axis AX2. As a result, the nozzle NZ1 can be moved to an outside of a region of the substrate W. Here, for example, when an on-off valve V5 is opened, a chemical liquid is discharged from a discharge opening 81A to the outside of the region of the substrate W. As shown in FIG. 18, the discharged chemical liquid is collected in a guard container 9 and drained from a drain 7A to an outside of a housing 11, for example.

The nozzle NZ1 in FIG. 17 is the nozzle NZ1 including the plurality of discharge openings 81A to 81E. In this regard, the nozzle NZ1 in FIG. 17 may be the plurality of nozzles NZ1 to NZ5 of the second embodiment.

According to the present embodiment, the nozzle NZ1 can be moved to an outside of the substrate W in plan view. As a result, pre-dispensing can be performed from the nozzle NZ1 to the outside of the substrate W. Specifically, the application in which the treatment liquid can be discharged to the outside of the region of the substrate W held by the spin chuck 3 can be used for the pre-dispensing. The pre-dispensing is an operation of preparing a fresh treatment liquid in a pipe by discharging the treatment liquid in the pipe before discharging the treatment liquid to the substrate W. For example, there is a case where it is desired to manage an oxygen concentration in the treatment liquid.

In the conventional substrate processing apparatus, since the nozzle is fixed above the substrate W, pre-dispensing cannot be performed from the nozzle. Therefore, the conventional substrate processing apparatus performs the pre-dispensing without using the nozzle, at a position on an upstream pipe away from the nozzle. For example, after performing the pre-dispensing, an inside of the pipe from the position of the pre-dispensing to the nozzle is empty, and there is a time lag in order to send a fresh treatment liquid to the nozzle. According to the present embodiment, since the pre-dispensing can be performed from the nozzle, the above-described time lag is suppressed, and a mechanism for performing the pre-dispensing provided in the middle of the pipe can be omitted. When the plurality of nozzles NZ1 to NZ5 are provided in the rotation nozzle plate 23, pre-dispensing can be performed from each of the nozzles NZ1 to NZ5 to the outside of the substrate W.

### Fourth embodiment

Next, a fourth embodiment of the present invention will be described with reference to the drawings. Note that description common to the first to third embodiments will be omitted. FIG. 19 is a longitudinal sectional view showing a schematic configuration of a substrate processing apparatus 1 according to the fourth embodiment.

In the first to third embodiments, the substrate processing apparatus 1 does not have a function of washing a lower surface of the shielding plate 21 and the lower surface of the rotation nozzle plate 23. In this regard, the fourth embodiment has the function.

Reference is made to FIG. 19. The substrate processing apparatus 1 includes a first cleaning nozzle 125, a second cleaning nozzle 127, and a cleaning nozzle rotation mechanism 129. The first cleaning nozzle 125 is provided on a lower surface of a rotation nozzle plate 23. The first cleaning nozzle 125 discharges a cleaning liquid along the lower surface of the rotation nozzle plate 23. In other words, the first cleaning nozzle 125 discharges the cleaning liquid in a horizontal direction. When a nozzle rotation mechanism 78 rotates the rotation nozzle plate 23 about a vertical axis AX2, a direction of the first cleaning nozzle 125 can be changed.

The second cleaning nozzle 127 is provided above a substrate W held by a spin chuck 3 and on a lower surface of a shielding plate 21. The second cleaning nozzle 127 discharges a cleaning liquid along the lower surface of the shielding plate 21. A base end portion 127A of the second cleaning nozzle 127 extends in a vertical direction Z. The second cleaning nozzle 127 is rotatable about a vertical axis AX3 passing through the center of the base end portion 127A. The cleaning nozzle rotation mechanism 129 rotates (swings) the second cleaning nozzle 127 about the vertical axis AX3. Accordingly, a direction of the second cleaning nozzle 127 can be changed. The cleaning nozzle rotation mechanism 129 includes an electric motor.

The substrate processing apparatus 1 includes a cleaning liquid supply mechanism 131 and a fifth inert gas supply mechanism 133. The cleaning liquid supply mechanism 131 includes cleaning liquid pipes 131A and 131B, an on-off valve V13, and a fifth pump. The cleaning liquid pipe 131A connects the first cleaning nozzle 125 and a cleaning liquid supply source 135. The cleaning liquid pipe 131B connects the second cleaning nozzle 127 and a branch pipe BN1 in the middle of the cleaning liquid pipe 131A. The on-off valve V13 and the fifth pump are provided in the cleaning liquid pipe 131A between the branch pipe BN1 and the cleaning liquid supply source 135. The fifth pump sends a cleaning liquid (for example, DIW) from the cleaning liquid supply source 135 to the first cleaning nozzle 125 and the second cleaning nozzle 127. The on-off valve V13 selectively supplies the cleaning liquid and stops the supply of the cleaning liquid.

The fifth inert gas supply mechanism 133 includes gas pipes 133A and 133B and an on-off valve V14. The gas pipe 133A connects the first cleaning nozzle 125 and a fifth inert gas supply source 137. The gas pipe 133B connects the second cleaning nozzle 127 and a branch pipe BN2 in the middle of the gas pipe 133A. The on-off valve V14 is provided in the gas pipe 133A between the branch pipe BN2 and the fifth inert gas supply source 137. The on-off valve V14 selectively supplies an inert gas from the fifth inert gas supply source 137 and stops the supply of the inert gas.

Next, an operation of the substrate processing apparatus 1 will be described. Cleaning using the first cleaning nozzle 125 and the second cleaning nozzle 127 is performed during substrate processing as shown in FIG. 19. For example, it is assumed that an acidic treatment liquid is discharged from a nozzle (or discharge opening) to the substrate W to perform a first treatment, and then an alkaline treatment liquid is discharged from another nozzle (or another discharge opening) to the substrate W to perform a second treatment. In order to suppress contact between the acidic treatment liquid and the alkaline treatment liquid, a cleaning treatment is performed between the first treatment and the second treatment.

First, the on-off valve V13 is opened. As a result, the cleaning liquid (for example, DIW) is discharged from each of the first cleaning nozzle 125 and the second cleaning nozzle 127. Thereafter, the nozzle rotation mechanism 78 swings the first cleaning nozzle 125 about the vertical axis AX2 while causing the cleaning liquid to be discharged. Consequently, the direction of the first cleaning nozzle 125 is changed, and the cleaning liquid can be discharged in a wide range. As a result, the lower surface of the shielding plate 21 and the lower surface of the rotation nozzle plate 23 can be cleaned (that is, the acidic treatment liquid is washed off).

The cleaning nozzle rotation mechanism 129 swings the second cleaning nozzle 127 about the vertical axis AX3 while causing the cleaning liquid to be discharged. Consequently, the direction of the second cleaning nozzle 127 is changed, and the cleaning liquid can be discharged in a wide range. As a result, the lower surface of the shielding plate 21 and the lower surface of the rotation nozzle plate 23 (including the first cleaning nozzle 125) can be further cleaned. When the discharge of the cleaning liquid is stopped, the on-off valve V13 is closed.

Thereafter, the on-off valve V14 is opened. As a result, the inert gas (for example, nitrogen) is discharged from each of the first cleaning nozzle 125 and the second cleaning nozzle 127. Thereafter, the nozzle rotation mechanism 78 swings the first cleaning nozzle 125 about the vertical axis AX2 while causing the inert gas to be discharged. The cleaning nozzle rotation mechanism 129 swings the second cleaning nozzle 127 about the vertical axis AX3 while causing the inert gas to be discharged. By discharging the inert gas, the lower surface of the shielding plate 21 and the lower surface of the rotation nozzle plate 23 can be dried.

According to the present embodiment, since the first cleaning nozzle 125 is provided on the lower surface of the rotation nozzle plate 23, the direction of the first cleaning nozzle 125 can be swung as the rotation nozzle plate 23 swings about the vertical axis AX2. The first cleaning nozzle 125 corresponds to a cleaning nozzle of the present invention.

A modification of the present embodiment will be described. In the present embodiment, the substrate processing apparatus 1 includes the first cleaning nozzle 125 and the second cleaning nozzle 127. In this regard, the substrate processing apparatus 1 may not include one of the first cleaning nozzle 125 and the second cleaning nozzle 127.

In the present embodiment, each of the first cleaning nozzle 125 and the second cleaning nozzle 127 discharges the cleaning liquid and the inert gas. In this regard, each of the first cleaning nozzle 125 and the second cleaning nozzle 127 may discharge only the cleaning liquid out of the cleaning liquid and the inert gas.

The first cleaning nozzle 125 and the second cleaning nozzle 127 simultaneously discharge the cleaning liquid, for example. In this regard, the first cleaning nozzle 125 and the second cleaning nozzle 127 may individually discharge the cleaning liquid. In addition, the first cleaning nozzle 125 and the second cleaning nozzle 127 may individually discharge the inert gas.

The present invention is not limited to the above described embodiments, and can be modified as follows.
(1) In the embodiments described above, in plan view, the virtual circle VC on which each nozzle is provided passes through the center of the substrate W held by the spin chuck 3. In this regard, the virtual circle VC may not pass through the center of the substrate W. That is, in plan view, the moved nozzle (for example, the nozzle NZ1) does not pass through the center of the substrate W.
(2) In the embodiments and the modification (1) described above, the cup 7 and the guard container 9 are integrally moved in the vertical direction Z. In this regard, the cup 7 and the guard container 9 may be moved individually in the vertical direction Z. For example, the guard lifting and lowering mechanism 10 may move the guard container 9 in the vertical direction Z, and another lifting and lowering mechanism may move the cup 7 in the vertical direction Z.
(3) In the embodiments and the modifications described above, the single nozzle NZ1 includes the plurality of discharge openings 81A to 81E. Each of the plurality of nozzles NZ1 to NZ5 includes the single discharge opening. For these nozzles, for example, the single nozzle NZ1 may include the single discharge opening 81A.
(4) In the embodiments and the modifications described above, the labyrinth seals 47 and 65 are provided. In this regard, if necessary, a contact seal such as an O-ring may be provided instead of at least one of the labyrinth seals 47 and 65. However, there is a possibility that a treatment liquid or an atmosphere enters a seal portion and dirties the seal portion in the contact seal. There is a possibility that the dirt is transferred to the substrate W.
(5) In the embodiments and the modifications described above, the substrate processing apparatus 1 includes the single cup 7. In this regard, the substrate processing apparatus 1 may not include the cup 7. In this case, the guard container 9 may have the function of the cup 7. The substrate processing apparatus 1 may include a plurality of cups 7. In this case, the plurality of cups 7 are accommodated in the guard container 9.
(6) In the embodiments and the modifications described above, the shielding plate 21 and the rotation nozzle plate 23 include the plurality of pairs of fitting members 39 and 41. In this regard, the shielding plate 21 and the rotation nozzle plate 23 may include only one pair of fitting members 39 and 41.
(7) In the embodiments and the modifications described above, the shielding plate 21 and the rotation nozzle plate 23 include the plurality of pairs of fitting members 39 and 41. In this regard, the shielding plate 21 and the rotation nozzle plate 23 may not include the fitting members 39 and 41. In this case, the supporting member 35 of the rotation nozzle plate 23 directly supports the supported member 37 of the shielding plate 21.
(8) In the embodiments and the modifications described above, the guard container 9 and the shielding plate 21 include the plurality of pairs of fitting members 43 and 45. In this regard, the guard container 9 and the shielding plate 21 may include only one pair of fitting members 43 and 45.
(9) In the embodiments and the modifications described above, as shown in FIG. 6, the third uneven portion 67 is provided on the upper surface of the flange 61 of the rotation nozzle plate 23, and the fourth uneven portion 69 is provided on the lower surface of the annular portion 63. In this regard, the third uneven portion 67 and the fourth uneven portion 69 may be disposed oppositely. That is, the third uneven portion 67 may be provided on the lower surface of the flange 61 of the rotation nozzle plate 23, and the fourth uneven portion 69 may be provided on the upper surface of the annular portion 63. In this case, the third uneven portion 67 on the lower surface of the flange 61 and the fourth uneven portion 69 on the upper surface of the annular portion 63 face each other with the gap GP2 interposed therebetween.
(10) In the embodiments and the modifications described above, for example, the inert gas may be supplied from the discharge opening 81D or the nozzle NZ4 into the internal space SP surrounded by the guard container 9, the shielding plate 21, and the rotation nozzle plate 23.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus that processes a substrate, comprising:
a chuck configured to hold the substrate in a horizontal posture;
a rotation mechanism configured to rotate the substrate held by the chuck, about a first vertical axis passing through a center of the substrate;
a guard container having a side wall surrounding a side of the chuck, and a guard opening formed by an upper inner peripheral edge of the side wall;
a shielding plate provided above the substrate held by the chuck, and is capable of closing the guard opening;
an inert gas supply mechanism configured to supply an inert gas into an internal space surrounded by the guard container and the shielding plate;
a rotation nozzle plate disposed in a mounting hole penetrating the shielding plate in a vertical direction, and is rotatable with respect to the shielding plate about a second vertical axis arranged at a position different from the first vertical axis;
a nozzle provided at a position away from the second vertical axis in the rotation nozzle plate, and configured to discharge a treatment liquid to the substrate held by the chuck; and
a nozzle rotation mechanism configured to rotate the rotation nozzle plate about the second vertical axis.

2. The substrate processing apparatus according to claim 1, wherein
the rotation nozzle plate includes a supporting member configured to support the shielding plate,
when the supporting member of the rotation nozzle plate supports the shielding plate, the rotation nozzle plate is configured to move integrally with the shielding plate in the vertical direction, and
when the shielding plate is supported on an upper portion of the guard container, the rotation nozzle plate is configured to be separated from the shielding plate.

3. The substrate processing apparatus according to claim 1, wherein
the nozzle rotation mechanism is configured to move the nozzle between the center of the substrate and a peripheral edge of the substrate in plan view, by rotating the rotation nozzle plate about the second vertical axis.

4. The substrate processing apparatus according to claim 1, wherein
the nozzle includes a plurality of discharge openings on a lower surface of the nozzle, and
a first discharge opening of the plurality of discharge openings is configured to discharge the treatment liquid.

5. The substrate processing apparatus according to claim 4, wherein
the nozzle is provided on a virtual circle with the second vertical axis as a central axis, in the rotation nozzle plate, and
the virtual circle is configured to pass through the center of the substrate held by the chuck in plan view.

6. The substrate processing apparatus according to claim 4, wherein
the nozzle is provided on a virtual circle with the second vertical axis as a central axis, in the rotation nozzle plate, and
the virtual circle is configured to pass through a position deviated from the substrate held by the chuck in plan view.

7. The substrate processing apparatus according to claim 1, further comprising
a plurality of nozzles including the nozzle, wherein
each of the plurality of nozzles is provided at a position away from the second vertical axis in the rotation nozzle plate.

8. The substrate processing apparatus according to claim 1, further comprising
a plurality of nozzles including the nozzle, wherein
the plurality of nozzles are provided on a virtual circle with the second vertical axis as a central axis, in the rotation nozzle plate.

9. The substrate processing apparatus according to claim 8, wherein
the virtual circle is configured to pass through the center of the substrate held by the chuck in plan view.

10. The substrate processing apparatus according to claim 8, wherein
the virtual circle is configured to pass through a position deviated from the substrate held by the chuck in plan view.

11. The substrate processing apparatus according to claim 1, further comprising
a cleaning nozzle provided on a lower surface of the rotation nozzle plate, and configured to discharge a cleaning liquid along the lower surface of the rotation nozzle plate.

12. The substrate processing apparatus according to claim 1, wherein
an upper portion of the guard container and a lower surface of a peripheral edge portion of the shielding plate have a labyrinth seal.

13. The substrate processing apparatus according to claim 1, wherein
the rotation nozzle plate has a flange protruding to an outer peripheral side,
the shielding plate has an annular portion protruding to the mounting hole, and
an upper surface of the flange and a lower surface of the annular portion have a labyrinth seal.

14. The substrate processing apparatus according to claim 12, wherein
the inert gas supply mechanism is configured to supply the inert gas to the labyrinth seal, and to supply the inert gas into the internal space via the labyrinth seal.

15. The substrate processing apparatus according to claim 1, wherein
the guard container includes a guard-side fitting member provided on an upper surface of the side wall,
the shielding plate includes a plate-side fitting member provided on a lower surface of the shielding plate, and
the plate-side fitting member is fitted to the guard-side fitting member.

16. The substrate processing apparatus according to claim 15, wherein
the guard container is configured not to be rotated about each of the first vertical axis and the second vertical axis.

17. The substrate processing apparatus according to claim 1, further comprising
a lifting and lowering mechanism configured to move the shielding plate and the rotation nozzle plate in the vertical direction.
